(19) United States
(12) Patent Application Publication
(10) Pub. No.: US 2024/0279809 A1
(43) Pub. Date: Aug. 22, 2024

(54) SHOWERHEAD AND SUBSTRATE TREATMENT APPARATUS INCLUDING SAME

(71) Applicant: HANWHA PRECISION MACHINERY CO., LTD., Changwon-si (KR)

(72) Inventors: Dong Won SEO, Changwon-si (KR); Sang Yeop KIM, Changwon-si (KR); Hui Seong RYU, Changwon-si (KR); Baek Ju LEE, Changwon-si (KR); Hyun Chul CHO, Changwon-si (KR); Min Ho CHEON, Changwon-si (KR); Pil Hee HAN, Changwon-si (KR)

(73) Assignee: HANWHA PRECISION MACHINERY CO., LTD., Changwon-si (KR)

(21) Appl. No.: 18/652,303

(22) Filed: May 1, 2024

Related U.S. Application Data
(63) Continuation of application No. PCT/KR2022/006541, filed on May 9, 2022.

(30) Foreign Application Priority Data
Nov. 3, 2021 (KR) 10-2021-0149334

(51) Int. Cl. C23C 16/455

(52) U.S. Cl. CPC C23C 16/45565; C23C 16/45544

(57) ABSTRACT

A substrate treatment apparatus includes a process chamber including a substrate treatment space and a disk on which a substrate is seated; and a showerhead provided on the process chamber, the showerhead including: a body; an inlet space in which a fluid is configured to flow through; and a plurality of spray holes provided on a lower surface of the body and configured to spray the fluid toward a substrate, where the plurality of spray holes are inclined at an angle with respect to the lower surface of the body.

### CROSS-REFERENCE TO RELATED APPLICATION(S)

This application is a continuation of International Application No. PCT/KR2022/006541, filed on May 9, 2022, in the Korean Intellectual Property Receiving Office, and Korean Patent Application No. 10-2021-0149334, filed on Nov. 3, 2021, in the Korean Intellectual Property Office, the disclosures of which are incorporated by reference herein in their entireties.

### BACKGROUND

The present disclosure relates to a showerhead and a substrate treatment apparatus including the same, and more particularly, to a showerhead capable of reducing a gap between a substrate and a spray surface of the showerhead, that is, a process gap, and a substrate treatment apparatus including the same.

A substrate treatment process of depositing a thin film on a semiconductor substrate may include various methods such as physical vapor deposition (PVD) and chemical vapor deposition (CVD), and recently, research on atomic layer deposition (ALD) has been actively conducted to manufacture high-performance and high-efficiency products.

The atomic layer deposition is a deposition method that forms a film by stacking atomic layers one by one on a substrate or wafer and may include ALD and plasma-enhanced atomic layer deposition (PEALD. In addition, the atomic layer deposition may be divided into a time division method that divides a reactant gas according to a time and a space division method that divides a reactant gas according to space.

The ALD of the space division method may include a plurality of areas divided into a deposition area, a purge area, etc. In the above-described ALD method, a substrate or wafer disposed on a disk may sequentially move through the plurality of areas by rotating the disk, and in this process, a set material may be deposited on the substrate or wafer.

The ALD of the time division method may include a gas supply process, a purge process, etc., which may be performed at a preset deposition time within a process chamber. For example, in the above-described ALD method, a process of supplying a source gas, a reactant gas, or the like into the chamber, a process of purging the gas, may be performed in a set order, and in this process, a set material may be deposited on a substrate or wafer to a set thickness.

A showerhead for spraying the reactant gas onto the substrate may be positioned in the process chamber, and a plurality of gas spray holes for spraying the reactant gas onto the deposited object, that is, the top of the substrate may be machined in the showerhead.

A plurality of gas spray holes for finally spraying the reactant gas toward the substrate may be machined in a vertical direction in a conventional showerhead.

A gap between the substrate and the showerhead, that is, a gap between the substrate and a spray surface of the showerhead, may be defined as a process gap, and since the gap is small, the productivity of the film deposition process may be improved. This gap may contribute to the productivity of the film deposition process.

Therefore, the deposition equipment is being developed to minimize the gap between the substrate and the spray surface of the showerhead, that is, the process gap.

However, the process gap may have a close influence on the amount of sprayed reactant gas, and if the process gap was too small, there may be a problem in that a shape of the gas spray hole of the showerhead is transferred to the surface of the substrate.

Due to the problem described above, the conventional showerhead may be limited in narrowing the gap between the substrate and the spray surface of the showerhead, that is, the process gap.

### SUMMARY

Provided is a showerhead capable of reducing a gap between a substrate and a spray surface of the showerhead, that is, a process gap, by forming a gas spray hole for spraying a reactant gas on the substrate to be inclined, and a substrate treatment apparatus including the same.

Further provided is a showerhead capable of evenly spraying a reactant gas over an entire surface of a substrate by alternately changing a spray direction of the reactant gas to the left and right, and a substrate treatment apparatus including the same.

Additional aspects will be set forth in part in the description which follows and, in part, will be apparent from the description, or may be learned by practice of the presented embodiments.

According to an aspect of the disclosure, a showerhead provided on a process chamber may include: a body; an inlet space in which a fluid is configured to flow through; and a plurality of spray holes provided on a lower surface of the body and configured to spray the fluid toward a substrate, where the plurality of spray holes are inclined at an angle with respect to the lower surface of the body.

A separation of the plurality of spray holes may increase from a center of the lower surface of the body to an edge of the lower surface of the body.

The inclination angle of the plurality of spray holes with respect to the lower surface of the body may be from 30° to 60°.

A density of a plurality of spray holes in a central portion of the lower surface of the body may be from 60% to 70% greater than a density of a plurality of spray holes in an outer portion of the lower surface of the body.

The plurality of spray holes may include: a plurality of first spray holes provided in a central portion of the lower surface of the body; and a plurality of second spray holes provided in an outer portion of the lower surface of the body excluding the central portion, where a first inclination angle of the plurality of first spray holes is smaller than a second inclination angle of the plurality of second spray holes with respect to the lower surface of the body.

An inclination angle of a number of first spray holes closest to a center of the lower surface of the body may be smaller than an inclination angle of other first spray holes and the inclination angle of the plurality of second spray holes, and an inclination angle of a number of second spray holes closest to an outer edge of the lower surface of the body may be larger than an inclination angle of other second spray holes and the inclination angle of the plurality of first spray holes.

The plurality of spray holes may include: a plurality of first spray holes with an inclination angle in a first direction, and a plurality of second spray holes with an inclination angle in a second direction different from the first direction, where the body includes a valve configured to selectively open and close a flow of fluid through the plurality of first spray holes and the plurality of second spray holes.

The valve may include: a plate comprising a plurality of openings corresponding with the plurality of first spray holes and the plurality of second spray holes, the plate configured to rotate and selectively align the plurality of openings with the plurality of first spray holes or the plurality of second spray holes within the inlet space; and a shaft configured to rotate the plate between an opened state and a closed state.

The plurality of first spray holes may be provided in one or more first straight lines passing through a center of the lower surface of the body, where the plurality of second spray holes are provided in one or more second straight lines passing through the center of the lower surface of the body, and where the one or more first straight lines alternate with the one or more second straight lines about the center of the lower surface of the body.

The plurality of openings on the plate may be provided in a plurality of straight lines corresponding to the plurality of first spray holes and the plurality of second spray holes, and in the opened state, the plurality of openings are aligned with either the plurality of first spray holes or the plurality of second spray holes.

The valve may further include: a first motor configured to rotate the plate between the opened state and the closed state; and a magnetic fluid seal providing a seal between the shaft and the process chamber.

The valve may further include a first motor connected to the shaft and configured to rotate the plate between the opened state and the closed state, and the first motor may be a step motor configured to rotate the plate at a preset angle in predetermined time intervals and alternately align the plurality of openings with the plurality of first spray holes and the plurality of second spray holes at each predetermined time interval.

The showerhead may further a second shaft configured to rotate the body of the showerhead.

The showerhead may further include a pipe protruding from the body and connected to a fluid supply and configured to supply the fluid into the inlet space, where the pipe comprises: a fixed pipe fixed to the process chamber; and a rotating pipe rotatably coupled to the fixed pipe about an axial direction, and where the second shaft includes: a second motor; and a transmission connected to the second motor and configured to transmit a rotational force to the rotating pipe.

The second motor may be provided on an upper portion of the process chamber, where the second shaft is provided through a surface of the process chamber, and where a magnetic fluid seal is provided between the second shaft and the process chamber.

According to an aspect of the disclosure, a process chamber comprising a substrate treatment space and a disk on which a substrate is seated; and a showerhead provided on an upper side of the disk in the process chamber and configured to spray a fluid toward the substrate seated on the disk, where the shower head includes: a body; an inlet space in which a fluid is configured to flow through; and a plurality of spray holes provided on a lower surface of the body and configured to spray the fluid toward a substrate, where the plurality of spray holes are inclined at an angle with respect to the lower surface of the body.

The disk may be provided with a plurality of pockets onto which the substrate is seated, where the plurality of pockets are configured to rotate on a plane via a first rotation assembly.

The disk may be provided on an bottom surface of the process chamber and configured to rotate by a second rotating assembly.

A separation of the plurality of spray holes of the showerhead may increase from a center of the lower surface of the body to an edge of the lower surface of the body.

The angle of the plurality of spray holes with respect to a lower surface of the body may be from 30° to 60°.

According to an aspect of the disclosure, a showerhead provided on a process chamber may include: a body; a pipe protruding from the body and connected to a fluid supply; an inlet space configured to accommodate fluid from the fluid supply; a plurality of spray holes provided on a lower surface of the body and configured to spray the fluid toward a substrate; and a valve configured to selectively open and close a flow of fluid through the plurality of spray holes, where the plurality of spray holes are inclined at an angle with respect to the lower surface of the body.

The valve may include: a plate comprising a plurality of openings corresponding with the plurality of spray holes, the plate configured to rotate and selectively align the plurality of openings with a number of the plurality of spray holes; and a shaft configured to rotate the plate between an opened state and a closed state.

The showerhead may further include a second shaft configured to rotate the body of the showerhead.

An inclination angle of a number of spray holes at an edge of the lower surface of the body may be larger than an inclination angle of a number of spray holes in a center of the lower surface of the body.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a schematic view illustrating a substrate treatment apparatus including a showerhead according to an embodiment of the present disclosure;

FIG. 2 is a perspective view illustrating a disk in the substrate treatment apparatus including the showerhead according to an embodiment of the present disclosure;

FIG. 3 is a cross-sectional view illustrating a showerhead according to an embodiment of the present disclosure;

FIG. 4 is a bottom view illustrating the showerhead according to an embodiment of the present disclosure;

FIGS. 5A and 5B are schematic diagrams for comparing the showerhead according to an embodiment of the present disclosure to a comparative example;

FIG. 6 is a cross-sectional view illustrating the showerhead according to an embodiment of the present disclosure;

FIG. 7 is a cross-sectional view illustrating the showerhead according to an embodiment of the present disclosure;

FIG. 8 is a bottom view illustrating the showerhead according to an embodiment of the present disclosure;

FIG. 9 is a cross-sectional view taken along line A-A′ of FIG. 8 according to an embodiment of the present disclosure;

FIG. 10 is a cross-sectional view taken along line B-B′ of FIG. 8 according to an embodiment of the present disclosure; and

FIG. 11 is a bottom view illustrating a rotating plate for opening and closing a flow path of the showerhead according to an embodiment of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

The term “or” includes any and all combinations of one or more of a plurality of associated listed items.

The terms “have,” “having,” “includes,” “comprises,” “including,” or “comprising,” when used in this specification, specify the presence of stated features, figures, steps, operations, components, members, or combinations thereof, but do not preclude the presence or addition of one or more other features, figures, steps, operations, components, members, or combinations thereof.

This disclosure references various components in the context of gas, but is not limited thereto. The components described herein should be construed as being applicable to the handling and control of any fluid.

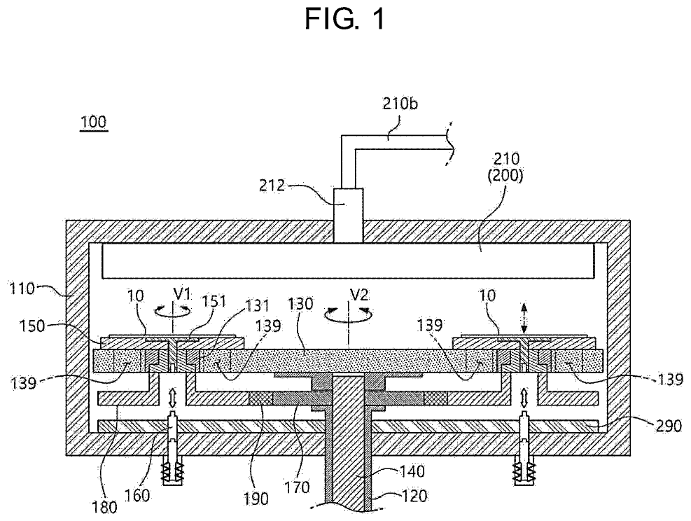

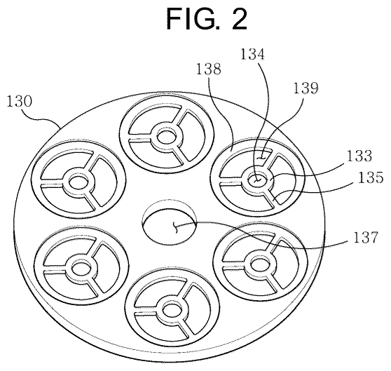

FIG. 1 is a schematic view illustrating a substrate treatment apparatus 100 including a showerhead 200 according to an embodiment of the present disclosure and FIG. 2 is a perspective view illustrating a disk in the substrate treatment apparatus 100 including the showerhead 200 according to an embodiment of the present disclosure.

A showerhead 200 according to an embodiment of the present disclosure and a substrate treatment apparatus 100 including the same will be described in detail below.

The substrate treatment apparatus 100 may include a process chamber 110 in which a substrate treatment space is formed and a disk 130 on which a substrate may be seated is provided.

In addition, a showerhead 200 positioned on an upper side of the disk and spraying a reactant gas toward the substrate seated on the disk is positioned in the process chamber 110.

The substrate treatment apparatus 100 according to an embodiment of the present disclosure may include a fluid supply that is connected to the showerhead 200 and supplies the fluid to the showerhead 200. The fluid being supplied may be a reactant gas.

The process chamber 110 may perform a substrate treatment process using plasma or the like. As an example, the process chamber 110 may provide a reaction space for an ALD process.

The showerhead 200 may be provided with a sprayer installed on a lid of the process chamber 110 to spray a source gas SG, a reactant gas RG, and a purge gas PG into different gas spray areas on the disk 130. It should be noted that the process chamber 110 may also be applied to substrate treatment methods other than ALD, CVD, and etching.

In the case of the ALD process, a substrate 10 may be sequentially exposed to the source gas, the purge gas, and the reactant gas by being moved in a set order through rotation of the disk 130. Accordingly, the substrate 10 may be sequentially exposed to each of the source gas, the purge gas, and the reactant gas as the disk 130 rotates, and as a result, a single-layer or multi-layer thin film may be deposited on the substrate 10 by an Atomic Layer Deposition (ALD) process.

In the ALD process, the source gas may be sprayed onto the substrate 10 facing a source gas area, the purge gas may be sprayed onto the substrate 10 facing a purge gas area, and the reactant gas may be sprayed onto the substrate 10 facing a reactant gas area.

In the ALD process, as the disk 130 rotates, one specific substrate 10 sequentially passes through the source gas area, the purge gas area, and the reactant gas area, and a single-layer or multi-layer thin film may be deposited thereon through the ALD (Atomic Layer Deposition) process.

The disk 130 may be disposed within the process chamber 110. The process chamber 110 may be provided with an accommodation space in which the substrate 10 corresponding to a processing object is accommodated.

Within the process chamber 110, treatment on the substrate 10 may be performed, such as a thin film deposition process for the substrate 10, a cleaning process for the substrate 10, and an etching process for the substrate 10.

In the case of the thin film deposition process, chemical vapor deposition (CVD) and physical vapor deposition (PVD) may be applied, and both may require thin film raw materials such as reactant gas and source gas.

In order to improve yield, a thin film may be deposited with a uniform thickness over the entire area of the substrate 10, such as a wafer or PCB, disposed in the process chamber 110. In addition, when a plurality of substrates 10 are disposed together in the process chamber 110, a thin film thickness of a specific substrate 10 and a thin film thickness of other substrates 10 may be uniform.

In order for the treatment for the substrate 10, including the thin film deposition, to be uniformly performed, a distribution range of a raw material diffused within the process chamber 110 may be uniform. However, it is realistically difficult to uniformly maintain a distribution of the raw material in the process chamber 110 and a distribution of plasma that provides energy necessary for treatment for the substrate 10. As a result, since the raw material distribution or plasma distribution within the process chamber 110 is non-uniform, it may be difficult to uniformly clean, deposit, or etch the substrate 10. As an example, the raw material or plasma may be concentrated in the center of the process chamber 110 in plan view. Therefore, based on one sheet of substrate 10, treatment on an area adjacent to the center of the process chamber 110 may performed more intensely than treatment on an area adjacent to an edge of the process chamber 110. Therefore, when depositing the thin film, a non-uniform problem may occur in which one side of the substrate 10 is deposited thicker than the other side thereof. Such a problem may also occur in a cleaning process and an etching process of the substrate 10.

An another example, when a first substrate 10 and a second substrate 10 are disposed together in the process chamber 110, a thin film thickness of the first substrate 10 and a thin film thickness of the second substrate 10 may vary due to a non-uniform distribution of the raw material or the distribution of plasma.

The present disclosure may provide uniformity to a treatment state of each area of a single substrate 10, regardless of the non-uniform distribution of raw material or the non-uniform distribution of plasma. Furthermore, the present disclosure may provide uniformity simultaneously to the treatment states of the plurality of substrates 10.

The substrate treatment apparatus 100 according to an embodiment of the present disclosure may use a pocket 150 to treat the plurality of substrates 10 together.

The pocket 150 may be installed on one surface of the disk 130 and may be formed in a plate shape on which the substrate 10 is seated. A seating groove 138 in which the substrate 10 is seated may be formed on one surface of the pocket 150 facing the substrate 10. The seating groove 138 may be formed in the same shape as a seating portion of the substrate 10 in order to prevent damage to the substrate 10 and ensure treatment for the substrate 10, such as deposition.

One or more pockets 150 may be installed on the disk 130.

The center of a plurality of pockets 150 formed in the disk 130 to treat the plurality of substrates 10 together may be different from the center of the chamber 110 in plan view. Therefore, the pocket 150 and one side of the substrate 10 seated in the pocket 150 may be disposed adjacent to the center of the process chamber 110, and the other side thereof may be disposed adjacent to the edge of the process chamber 110. In this case, a first rotating assembly and a second rotating assembly may be used to prevent the substrate 10 from being non-uniformly treated.

The first rotating assembly may perform a first rotation with respect to the pocket 150. In this case, the pocket 150 may be formed in a circular shape in plan view to accommodate the first rotation.

The first rotation of the pocket 150 means that the pocket 150 rotates around the center of the pocket 150 as the center of rotation in plan view, and will hereinafter be referred to as the rotation of the pocket 150. However, the first rotation of the pocket 150 may mean that the pocket 150 rotates more than 360 degrees with respect to the process chamber 110.

The second rotating assembly may perform a second rotation with respect to the pocket 150.

Compared to the first rotation of the pocket 150, the second rotation of the pocket 150 may mean that the pocket 150 rotates around a virtual rotation axis provided outside the pocket 150 as the center of rotation. In this case, the virtual rotation axis may be provided at the center of the process chamber 110 or the center of the disk 130. In this case, the second rotation of the pocket 150 may be referred to as a revolution rotating around the virtual rotation axis.

As an example, the second rotating assembly may rotate the disk 130 on which the plurality of pockets 150 are installed with the center of the disk 130 as the rotation center in order to rotate the pocket 150.

According to the rotation of the pocket 150, since an area on one side of the substrate 10 seated in the pocket 150 toward the center of the process chamber 110 is not fixed and changes from time to time, the entire area of the substrate 10 may be uniformly treated. As an example, according to the first rotating assembly, a thin film of uniform thickness may be deposited on both one side and the other side of the substrate 10, and the thin film may be deposited on the substrate 10 to a constant thickness without distinction of area. In the case of cleaning or etching, the entire area of the substrate 10 may be cleaned or etched to an even depth.

When the first substrate 10 is disposed at a first position and the second substrate 10 is disposed at a second position within the process chamber 110, the raw material density or plasma density at the first position may be different from the raw material density or plasma density at the second position. Accordingly, the thickness of the thin film deposited on the first substrate 10 and the thickness of the thin film deposited on the second substrate 10 may be different from each other. The second rotating assembly may rotate the disk 130 to revolve the pocket 150 so that the thickness of the thin film deposited on the first substrate 10 and the thin film deposited on the second substrate 10 are uniform.

As an example, when the first substrate 10 and the second substrate 10 alternately pass through the first position and the second substrate 10 by the second rotating assembly, the thickness of the thin films of the first substrate 10 and the second substrate 10 may be uniform.

According to an embodiment of the present disclosure, uniformity of treatment of the single substrate 10 may be improved by the first rotating assembly, and uniformity of treatment between the plurality of substrates 10 may be improved by the second rotating assembly. As a result, according to the rotation and revolution of the pocket 150, the overall yield of the substrate 10 may be improved.

The first rotating assembly and the second rotating assembly may be independently driven. When the first rotating assembly performs a first rotation with respect to the pocket 150 at a first speed V1 and the second rotating assembly moves the disk 130 at a second speed V2, V1 and V2 may be independently adjusted to ensure uniformity of thin film thickness, etc.

The substrate treatment apparatus 100 of the present disclosure may be provided with an controller that separately controls the first rotating assembly and the second rotating assembly. After checking the treatment results for the substrate 10, the user may use the adjusting portion to separately adjust the first speed V1 of the first rotating portion and the second speed V2 of the second rotating portion. The controller may be physically implemented by analog and/or digital circuits including one or more of a logic gate, an integrated circuit, a microprocessor, a microcontroller, a memory circuit, a passive electronic component, an active electronic component, an optical component, and the like, and may implement or execute software and/or firmware to perform the functions or operations described herein. The determination module may be implemented by one or more software modules and/or firmware.

As a comparative example, a case in which the first rotating assembly and the second rotating assembly are linked to each other will be described. In this case, the first speed V1 of the pocket 150 and the second speed V2 of the disk 130 may be interlocked.

When the first speed V1 is adjusted to a1 to improve the uniformity of treatment of the single substrate 10, the second speed V2 may also be forcibly determined to be b1. In this case, there is no particular problem as long as the uniformity of treatment between each substrate 10 is satisfactory, but even if the uniformity of treatment between each substrate 10 is unsatisfactory, a second speed V2 to b1 may be set. Therefore, a problem in which the uniformity of treatment for the single substrate 10 is satisfactory, but the uniformity of treatment between the plurality of substrates 10 is unsatisfactory may occur.

Conversely, if the second speed V2 is adjusted to b2, the first speed V1 may be forcibly determined to be a2. In this case, the uniformity of treatment between each substrate 10 may satisfy a design value, but the uniformity of treatment for the single substrate 10 may not satisfy the design value.

On the other hand, the substrate treatment apparatus 100 according to an embodiment of the present disclosure, since the first rotating assembly and the second rotating assembly may be driven independently of each other, the first speed V1 of the pocket 150 may be adjusted to a1, and the second speed V2 of the disk 130 may be adjusted to b2. Therefore, according to an embodiment of the present disclosure, while the uniformity of treatment of the single substrate 10 may satisfy the design value, the uniformity of treatment between the plurality of substrates 10 may also satisfy the design value.

If the first rotating assembly that rotates the pocket 150 is fixed to the process chamber 110, the rotation of the disk 130 and the revolution of the pocket 150 due to the rotation of the disk 130 may be limited by the first rotating assembly.

In order for the disk 130 to move smoothly by the second rotating assembly, the first rotating assembly may rotate the pocket 150 while moving together with the disk 130.

As an example, when the disk 130 performs a linear reciprocating motion, the first rotating assembly may also perform a linear reciprocating motion together with the disk 130. When the disk 130 performs a rotating motion, the first rotating assembly may also perform a rotating motion together with the disk 130. A relative speed between the disk 130 and the first rotating assembly may converge to 0.

The first rotating assembly may be provided with a first motor that rotates the pocket 150 and a link that transmits a rotational power of the first motor to the pocket 150 between the first motor and the pocket 150.

As an example, the link may be provided with a pocket gear 180 connected to the pocket 150, a main gear 170 linked to the pocket gear 180, and a first motor that rotates the main gear 170. When the main gear 170 rotates together with a first rotation shaft 140, the first motor may rotate the first rotation shaft 140. In order to improve the uniformity of treatment of the single substrate 10, the first rotation shaft 140 may be formed at the center of the pocket 150.

When the first motor rotates, the first rotation shaft 140 connected to a motor shaft of the first motor may rotate. By rotation of the first rotation shaft 140, the main gear 170 may rotate and the pocket gear 180 linked to the main gear 170 may rotate. When the pocket gear 180 rotates, the pocket 150 may perform a rotation (first rotation).

When the motor shaft of the first motor rotates, the pocket 150 may rotate with respect to the disk 130 as the first rotation shaft 140 connected to the motor shaft of the first motor rotates regardless of whether the disk 130 rotates.

In order to rotate the pocket 150 without limiting the revolution of the pocket 150, the first motor that rotates the pocket 150 may revolve around a second rotation shaft 120 along with the pocket 150.

If the first rotation shaft 140 and the second rotation shaft 120 are disposed on the same axis, the first motor may be fixed in one place.

As an example, the second rotation shaft 120 may be formed in a shape of a hollow pipe. In this case, the first rotation shaft 140 may be rotatably inserted into the hollow of the second rotation shaft 120. Accordingly, only the second rotation shaft 120 may externally penetrate through the process chamber 110. Further, the first rotation shaft 140 may be formed in a shape of a hollow pipe and the second rotation shaft 120 may be inserted into the hollow of the first rotation shaft 140.

The pocket 150 and the disk 130 may rotate in different rotation directions and at different rotation speeds by the first and second motors that are separately controlled by the controller.

A lift 151 for elevating the substrate 10 may be provided in the center of the pocket 150. The substrate 10 may be spaced apart from the seating groove 138 of the pocket 150 when the lift 151 ascends, and may be seated in the seating groove 138 when the lift 151 descends.

A thin film may be deposited on the substrate 10 seated on a bottom surface of the seating groove 138, and in this case, a portion of the thin film may also be deposited on an edge of the pocket 150 having a larger diameter than the substrate 10. Accordingly, the substrate 10 and the pocket 150 may be partially adhered to each other by the thin film, and the adhesion may be separated by the lift 151. In this case, the substrate 10 may be damaged by pressure of the lift applied to disconnect the adhesion. In addition, in the process of removing the adhesion through the elevation of the lift 151, a phenomenon in which the substrate 10 is tilted and falls from the lift 151 may occur.

In order to prevent the damage to the substrate 10, the lift 151 of the present disclosure may be structured accordingly.

In order to distribute the pressure applied to the substrate 10 by the process of removing the adhesion, etc., the lift 151 may be provided with a plate extending parallel to the bottom surface of the seating groove 138 of the pocket 150. Since the plate is in surface contact with the substrate 10, the plate may evenly distribute the pressure applied to the substrate 10, and may reliably prevent the substrate 10 from being tilted during the elevating process.

In order to protect the substrate 10, the plate may be parallel to the bottom surface of the seating groove 138 of the pocket 150. The lift 151 may be provided with an extension extending downward from the center of the plate so that the plate is parallel to the bottom surface of the seating groove 138. The extension direction of the extension may be the same as the elevating direction of the plate. The extension portion may be installed to penetrate through a first through hole 134 formed in the disk 130. In this case, the first through hole 134 may extend from an upper surface to a lower surface of the disk 130.

A side surface of the lift 151 may be formed into a ‘T’ shape by the plate and the extension. In this case, the extension may ascend or descend while sliding in the first through hole 134 of the disk 130. The extension portion guided by the first through hole 134 may be prevented from being tilted differently in the elevating direction, and the plate connected to the extension may also always be maintained parallel to the bottom surface of the seating groove 138 of the pocket 150.

The process chamber 110 may be provided with a lift driver 160 that pushes the extension upward or pulls the extension downward.

The first rotating assembly may be disposed to face a bottom surface of the disk 130. In this case, when the disk 130 or the pocket 150 moves, the lift driver 160 may maintain a state that is downward descended so as to be spaced apart from the first rotating assembly. In this case, the lift 151 may be in a state that is descended due to its own weight. The lift driver 160 may ascend when the disk 130 and the pocket 150 are stopped and physically push up the extension of the lift 151 exposed to the bottom surface of the disk 130.

The pocket 150 may be installed to face the first through hole 134 of the disk 130, and may be connected to the pocket gear 180 through the first through hole 134 of the disk 130. In this case, a shaft 131 that allows rotation of the pocket gear 180 or the pocket 150 may be interposed between the pocket gear 180 and the first through hole 134 or between the pocket 150 and the first through hole 134. The shaft 131, which is an element connected to the pocket 150, may be rotatably supported on the disk 130. As an example, the shaft 131 may form the first rotation shaft 140 that becomes a rotation center of the pocket 150 and may include a bearing. The bearing may be rotatably supported on the disk 130.

A heater 290 may be provided in the substrate treatment apparatus 100. The heater 290 may be installed in the process chamber 110 and may heat the substrate 10 to a set temperature. The set temperature at this time may be determined as a temperature at which treatment of the substrate 10, such as thin film deposition, is smoothly performed. The heater 290 may be installed between the disk 130 and the bottom surface of the process chamber 110. When the pocket 150 is installed on one side of the disk 130, the heater 290 may be installed on the other side of the disk 130 within the process chamber 110.

The pocket 150 may serve to receive heat from the heater 290 installed on a lower side of the disk 130 and transfer the heat to the substrate 10.

However, the heater 290 may be obscured from the pocket 150 by the disk 130 disposed between the heater 290 and the substrate 10. Since the first through hole 134 formed in the disk 130 is for installation of the shaft 131 and the lift 151, the first through hole 134 may be in a closed state when the shaft 131 and the leaf are installed. As a result, the heater 290 may be completely obscured from the pocket 150 by the disk 130.

A thermal hole 139 through which the heat generated by the heater 290 passes may be separately formed on the installation surface of the disk 130 where the pocket 150 is installed so that the heat from the heater 290 passes through the disk 130 and is directly applied to the pocket 150. The heat generated from the heater 290 may pass through the thermal hole 139 and to the pocket 150.

When a plurality of pockets 150 are provided on the disk 130, the thermal hole 139 may be formed at each position facing each pocket 150. In this case, the heater 290 may be installed at a position facing the thermal hole 139. The heater 290 and the disk 130 may be formed to move relative to each other so that the plurality of thermal holes 139 alternately pass through a position facing a specific point of the heater 290.

As an example, in a state in which the heater 290 is fixed to the process chamber 110, the thermal hole 139 may revolve along with the pocket 150.

Even if the heat of the heater 290 is different for each portion, the plurality of pockets 150 may be evenly heated through the revolving thermal hole 139. In order to more reliably and uniformly heat the plurality of pockets 150, the heater 290 may rotate around the second rotation shaft 120, which is the rotation center of the disk 130.

FIG. 2 is a perspective view illustrating the disk 130 of the present disclosure.

When the seating groove 138 in which the pocket 150 is seated is formed on one surface of the disk 130, the thermal hole 139 may be formed in the center of the bottom surface of the seating groove 138. To support the pocket 150, a diameter of the thermal hole 139 may be formed to be smaller than a diameter of the pocket 150.

Due to the difference in diameter between the thermal hole 139 and the pocket 150, the center of the pocket 150 seated in the seating groove 138 may face the thermal hole 139, and the edge of the pocket 150 seated in the seating groove 138 may be rotatably supported by an edge of the bottom surface of the seating groove 138.

When the pocket 150 is installed on the disk 130 to be able to rotate, the shaft 131, such as the bearing, needs to be supported on the disk 130. However, according to the thermal hole 139 having a larger diameter than the shaft 131, the shaft 131 may be in an unrealistic state floating in the center of the thermal hole 139.

For installation of the shaft 131, the substrate treatment apparatus 100 of the present disclosure is provided with an installation groove 133 formed in the center of the thermal hole 139, and a joint 135 connecting the installation groove 133 and the disk 130 across the thermal hole 139.

The shaft 131 that becomes the rotation center of the pocket 150 may be installed in the installation groove 133. As an example, the installation groove 133 may be formed in a ring shape having the first through hole 134 where the shaft 131 is installed. The pocket 150 may be installed on the disk 130 to be rotatable around the shaft 131 with respect to the disk 130.

In order to reliably support the installation groove 133, a plurality of joints 135 may be provided. Each joint 135 may be provided at different angles around the installation groove 133. Each joint 135 may be installed at an equal angle around the installation groove 133.

The thermal hole 139 may be divided into a plurality of pieces by a plurality of joints 135. The joint 135 may function as a covering plate for covering the thermal hole 139 with respect to the pocket 150. Therefore, each joint 135 may be formed in a bar shape so that an area of the thermal hole 139 covered by the joint 135 is minimized. Each of the plurality of divided thermal holes 139 may be formed in a fan shape due to the joint 135 formed in the bar shape.

When the lift 151 for elevating the substrate 10 is provided in the center of the pocket 150, a lift hole 132 through which the lift driver 160 passes, which pushes or pulls the lift 151 upward or downward, may be formed in the center of the shaft 131.

When the disk 130 is installed to be rotatable with respect to the process chamber 110, a second through hole 137 in which the second rotation shaft 120 and the like are installed may be formed in the center of the disk 130.

The disk 130 may receive heat from the heater 290 and evenly transfer the received heat to the substrate 10. A heat blocking film may exist on the side surface of the disk 130 with a very narrow gap, and heat loss to an inner sidewall of the chamber may be minimized due to the heat blocking film.

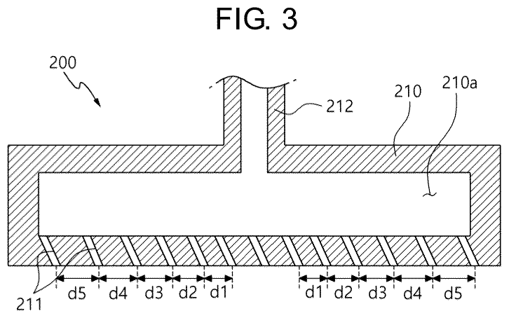

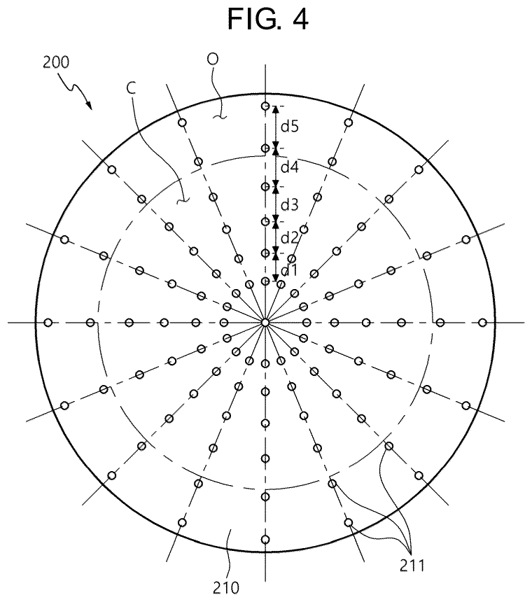

FIG. 3 is a cross-sectional view illustrating the showerhead 200 according to an embodiment of the present disclosure, FIG. 4 is a bottom view illustrating the showerhead 200 according to an embodiment of the present disclosure, and the showerhead 200 according to an embodiment of the present disclosure will be described in detail below with reference to FIGS. 3 and 4. The showerhead 200 according to an embodiment of the present disclosure, the showerhead 200 may be positioned on an upper side of the disk inside the process chamber 110 and spray a reactant gas for process treatment of the substrate toward a lower surface.

The showerhead 200 may include a showerhead body 210 in which a gas inlet space 210a through which a reactant gas is introduced is positioned, and a plurality of gas spray holes 211 for spraying the reactant gas toward the substrate are positioned on a lower surface thereof.

A pipe 212 for gas supply connected to the fluid supply may be positioned to protrude on an upper portion of the showerhead body 210.

The showerhead body 210 may be positioned so that the protruding pipe 212 for gas supply protrudes at the center of an upper side thereof, is connected to a gas supply pipe 210b of the reactant gas supply, receives the reactant gas through the pipe 212 for gas supply, and sprays the reactant gas through the plurality of gas spray holes 211 positioned on the lower surface thereof.

The gas spray hole 211 may be formed to be inclined by being tilted to one side relative to the lower surface of the showerhead body 210.

The plurality of gas spray holes 211 may be radially positioned from the center of the showerhead body 210, and the plurality of gas spray holes 211 may be positioned on a plurality of straight lines passing through the center of the showerhead body 210 and formed at different angles so as not to overlap each other.

In addition, the plurality of gas spray holes 211 may be distributed so that distribution density gradually increases from the center to the edge of the showerhead body 210, that is, a gap between the gas spray holes increases, thereby evenly spraying the reactant gas on the surface of the substrate.

The gap between the gas spray holes 211 may be narrowed in the order closer to the center of the showerhead body 210 and may be defined as d₁<d₂<d₃<d₄<d₅.

In addition, the plurality of gas spray holes 211 may have the distribution density of a central portion C from the center of the showerhead body 210 to an area of 60% to 70% more densely distributed than the distribution density of the remaining outer portion O, thereby evenly spraying the reactant gas on the surface of the substrate.

For example, the density of the plurality of gas spray holes 211 disposed in the outer portion may be less than about 80% of the density of the plurality of gas spray holes 211 disposed in the central portion. The density of the plurality of gas spray holes 211 disposed in the outer portion may be less than about 70% of the density of the plurality of gas spray holes 211 disposed in the central portion. Accordingly, the embodiment may evenly provide the reactant gas to the surface of the substrate.

That is, the reactant gas sprayed through the inclined gas spray hole 211 may move from the center to the edge of the substrate after being sprayed, and therefore, by having a high distribution density of the gas spray holes 211 in the central portion of the showerhead body 210 and a low distribution density of the gas spray holes 211 in the edge portion of the showerhead body 210, an amount of used gas may be reduced compared to the case in which the gas spray holes 211 are uniformly distributed on the lower surface of the showerhead body 210. Accordingly running costs may be reduced.

The gas spray hole 211 may be formed to be inclined by being tilted to one side to increase a movement path of the reactant gas, thereby reducing the gap between the substrate and the spray surface of the showerhead, that is, the process gap, and as the process gap narrows, a problem in which the shape of the gas spray hole 211 of the showerhead is transferred to the surface of the substrate is solved.

The gas spray hole 211 may also be positioned to be tilted to the right or tilted to the left.

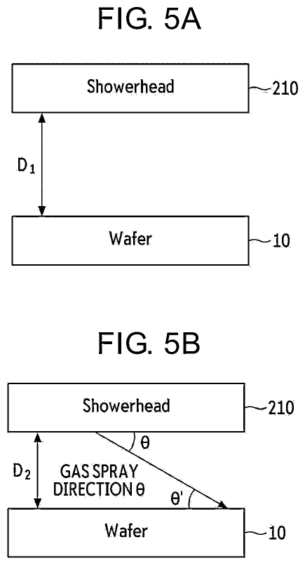

FIG. 5 is a schematic diagram comparing an embodiment of the showerhead 200 according to the present disclosure with a comparative example, FIG. 5(a) is a diagram illustrating a comparative example in which the gas spray hole 211 of the showerhead 200 is formed in a vertical direction, and FIG. 5(b) is a diagram illustrating an example in which the gas spray hole 211 of the showerhead 200 is positioned to be inclined at an inclination angle θ.

Referring to FIG. 5, when the gas spray hole 211 is positioned to be inclined at a preset inclination angle θ based on the lower surface of the flat showerhead body 210, a gas movement distance may be increased by a ratio of 1/sin θ compared to a distance of the reactant gas in the vertical direction, and accordingly, the gas movement distance may be increased compared to the process gap by the process gap×sin θ.

Accordingly, at the time of actual design, even if the process gap D2 of the embodiment is reduced by the comparative process gap D1 when the gas spray hole 211 is formed in the vertical direction, that is, the gas spray hole 211×sin θ in the existing vertical direction, the problem in which the shape of the gas spray hole 211 of the showerhead is transferred to the surface of the substrate may not occur.

That is, the gas movement distance may be increased by the process gap×sin θ, and the process gap may be reduced by the increased gas movement distance.

The inclination angle of the gas spray hole with respect to the lower surface of the showerhead body 210 may be less than 90°. The inclination angle of the gas spray hole with respect to the lower surface of the showerhead body 210 may be less than 70°. The inclination angle of the gas spray hole with respect to the lower surface of the showerhead body 210 may be from 30° to 60°.

As an example, since the gas movement distance of the reactant gas is increased by sin(30°) when the comparative process gap is 1 and the gas spray hole 211 is formed to be inclined at 30°, the process gap of the embodiment may be designed to be 1−1×sin(30°)=0.5 when actually designing the process chamber 110.

Since the movement distance of the reactant gas is increased by sin(45°) when the process gap is 1 and the gas spray hole 211 is formed to be inclined at 45°, the process gap of the embodiment may be designed to be 1−1×sin(45°) when actually designing the process chamber 110.

Since the movement distance of the reactant gas is increased by sin(60°) when the process gap is 1 and the gas spray hole 211 is formed to be inclined at 60°, the process gap of the embodiment may be designed to be 1−1×sin(60°) when actually designing the process chamber 110.

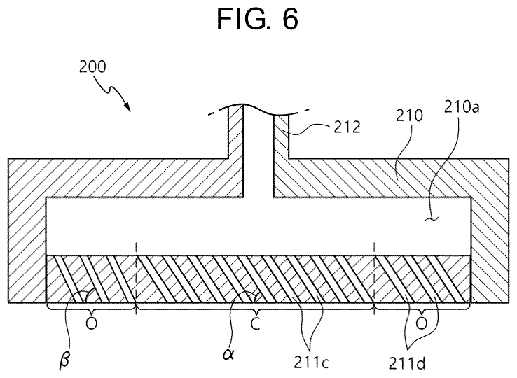

FIG. 6 is a cross-sectional view illustrating the showerhead according to an embodiment of the present disclosure. Referring to FIG. 6, the gas spray hole 211 may include a plurality of first spray holes 211c positioned in the central portion C from the center of the showerhead body 210 to an area of 60% to 70%, and a plurality of second spray holes 211d positioned in the outer portion O excluding the central portion C, inclination angles of the first spray hole 211c and the second spray hole 211d may be formed to be different from each other, and a second inclination angle β of the second spray hole 211d may be formed to be greater than a first inclination angle α of the first spray hole 211c.

That is, as illustrated in FIG. 3, the gas spray holes 211 may be formed at the same angle, and as illustrated in FIG. 6, the first inclination angle α of the plurality of first spray holes 211c positioned in the central portion C and the second inclination angle β of the plurality of second spray holes 211d positioned in the remaining outer portion O may be different from each other.

In addition, as the second inclination angle β of the second spray hole 211d may be formed to be greater than the first inclination angle α of the first spray hole 211c, the plurality of gas spray holes 211 positioned on a straight line passing through the center of the showerhead body 210 may be positioned in the following order from left to right: the outer portion O with a large inclination angle, the central portion C with a small inclination angle, and the outer portion O with a large inclination angle.

Since the first inclination angle α of the first spray hole 211c may be smaller than the second inclination angle β of the second spray hole 211d positioned in the remaining outer portion O, the reactant gas supplied to the center of the substrate through the first spray hole 211c may quickly move to the surrounding area.

In addition, since the second inclination angle β of the second spray hole 211d in the outer portion O may be greater than the first inclination angle α of the first spray hole 211c positioned in the central portion C, the reactant gas supplied to the outer portion of the substrate through the second spray hole 211d has a high concentration, which may improve reactivity.

In addition the plurality of first spray holes 211c may have different inclination angles, and the plurality of second spray holes 211d may have different inclination angles.

The plurality of first spray holes 211c and the plurality of second spray holes 211d may each be formed in a structure in which the inclination angle thereof increases from the center to the edge area.

That is, the first spray hole 211c disposed in the area closest to the center of the lower surface of the showerhead body 210 among the plurality of first spray holes 211c may have the smallest inclination angle compared to the other first spray holes 211c and the plurality of second spray holes 211d.

In addition, the second spray hole 211d disposed at the edge of the lower surface of the showerhead body 210, that is, the area closest to the edge may have the largest inclination angle compared to the other second spray holes 211d and the plurality of first spray holes 211c.

In addition, the inclination angle of the first spray hole 211c positioned furthest from the center of the showerhead body 210 among the plurality of first spray holes 211c may be smaller than the inclination angle of the second spray hole 211d closest to the center of the showerhead body 210 among the plurality of second spray holes 211d.

That is, the maximum inclination angle among the plurality of first spray holes 211c may be formed to be smaller than the minimum inclination angle among the plurality of second spray holes 211d.

Accordingly, as described above, the reactant gas supplied to the central portion of the substrate may quickly move to the surrounding area and the concentration of the reactant gas sprayed on the substrate may be increased, and may maximize reactivity and reaction efficiency.

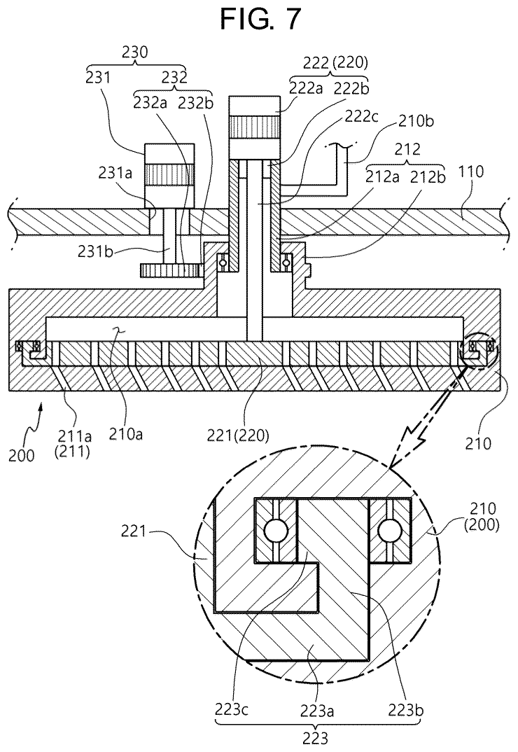

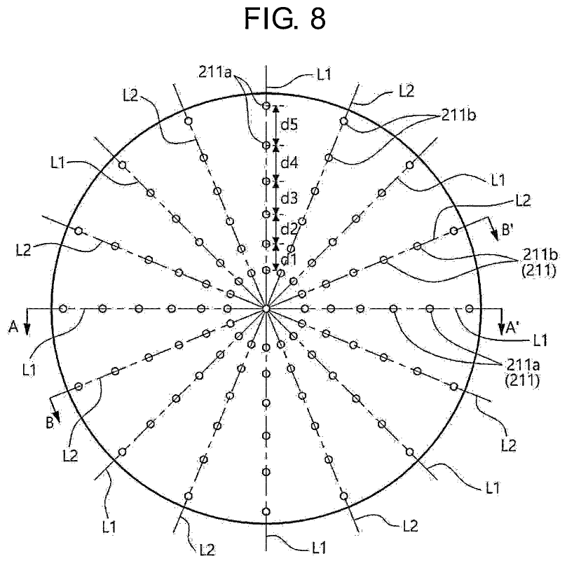

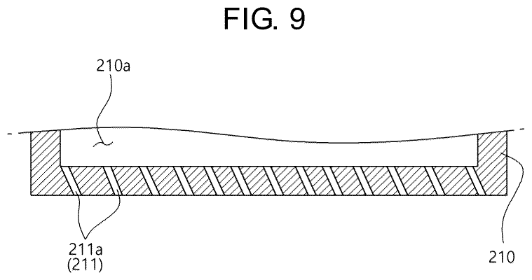

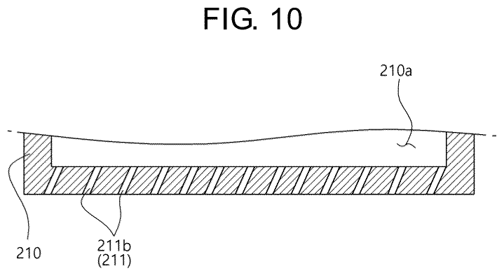

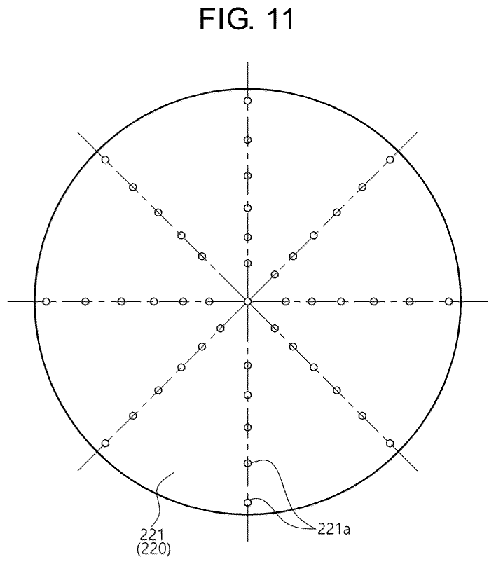

FIG. 7 is a cross-sectional view illustrating the showerhead 200 according to an embodiment of the present disclosure, FIG. 8 is a bottom view illustrating the showerhead 200 according to an embodiment of the present disclosure, FIG. 9 is a cross-sectional view taken along line A-A′ of FIG. 8, FIG. 10 is a cross-sectional view taken along line B-B′ of FIG. 8, and FIG. 11 is a bottom view illustrating a rotating plate 221 for opening and closing a flow path in the showerhead 200 according to an embodiment of the present disclosure.

The showerhead 200 according to an embodiment of the present disclosure will be described in detail below with reference to FIGS. 7 to 11.

The showerhead 200 according to an embodiment of the present disclosure, the plurality of gas spray holes may include a plurality of first gas spray holes 211a inclined in one direction, and a plurality of second gas spray holes 211b inclined in a different direction from the first gas spray holes 211a, and the showerhead 200 may further include a valve 220 positioned within the showerhead body 210 to selectively open and close the plurality of first gas spray holes 211a and the plurality of second gas spray holes 211b.

The plurality of first gas spray holes 211a may be positioned to be spaced apart from each other on one or more first straight lines L1 passing through the center of the lower surface of the showerhead body 210, the plurality of second gas spray holes 211b may be positioned to be spaced apart from each other on one or more second straight lines L2 passing through the center of the showerhead body 210, and the first straight lines L1 and the second straight lines L2 may be alternately positioned at the center of the lower surface of the showerhead body 210.

Since the first gas spray hole 211a and the second gas spray hole 211b may be inclined in different directions to spray gas in different directions and may be inclined in opposite directions, that is, have angles that may be symmetrical to each other, and may thereby allow the reactant gas to be evenly sprayed from both directions on the upper portion of the substrate when being alternately opened.

The first straight line portion L1 and the second straight line portion L2 may be alternately positioned at a preset angular interval at a radius of 360 degrees from the center of the showerhead body 210 and may be positioned to have the same interval of angle α as each other, so as to selectively open and close the first gas spray hole 211a of the first straight line portion L1 and the second gas spray hole 211b of the second straight line L2 with a rotating plate 221 for opening and closing a flow path, which will be described later.

As an example, the first straight line L1 and the second straight line L2 may be alternately positioned at intervals of an angle α of, for example, 22.5°, forming a total of 16 pieces of 8 each, so that a circular bottom surface of the showerhead body may be divided into 16 from the center of the showerhead body, and may be implemented in various ways as an example of equally dividing the circular bottom surface of the showerhead body from the center of the showerhead body.

In addition, the plurality of first gas spray holes 211a on the first straight lines L1 and the plurality of second gas spray holes 211b on the second straight lines L2 may have the same diameter, and may have a structure that can be selectively opened and closed by a plurality of openings 221a positioned in a row at corresponding intervals.

The valve 220 may include a rotating plate 221 for opening and closing a flow path having a plurality of openings 221a connected to only one side of the plurality of first gas spray holes 211a and the plurality of second gas spray holes 211b and rotatably positioned within the gas inlet space 210a, and a shaft 222 for opening and closing a spray hole, which rotates the rotating plate 221 for opening and closing the flow path.

The plurality of openings 221a may be positioned on a plurality of straight lines that pass through the center of the showerhead body 210 and may be formed at different angles so as not to overlap each other, and may each be positioned on a straight line that may be connected to either the first gas spray hole 211a of the first straight line portion L1 or the second gas spray hole 211b of the second straight line portion L2. For instance, the openings may be positioned on a plurality of straight lines that pass through the center of the lower surface of the showerhead body as to correspond with the plurality of first gas spray holes and the plurality of second gas spray holes, but not at the same time.

When the first straight lines L1 and the second straight lines L2 are alternately positioned, the plurality of openings 221a may be positioned on a straight line positioned to correspond to an angle between the first straight lines L1 and an angle between the second straight line L2, may thereby close the second gas spray hole 211b of the second straight line L2 when opening the first gas spray hole 211a of the first straight line L1, and may close the first gas spray hole 211a of the first straight line L1 when opening the second gas spray hole 211b of the second straight line portion L2.

As an example, when the first straight line portion L1 and the second straight line portion L2 are alternately positioned at intervals of an angle α of, for example, 22.5°, the plurality of openings 221a may be positioned on a straight line passing through the center of the rotating plate 221 for opening and closing the flow path and may be positioned at an interval corresponding to the first gas spray hole 211a or the second gas spray hole 211b on plurality of straight lines passing through the center of the rotating plate 221 for opening and closing the flow path and having intervals of 45°, thereby selectively opening and closing the first gas spray hole 211a or the second gas spray hole 211b.

The shaft 222 for opening and closing the spray hole may include a rotation motor 222a (e.g., a first motor) for opening and closing a spray hole positioned outside the process chamber 110, and a magnetic fluid seal 222b that seals between a rod 222c of the rotation motor 222a for opening and closing the spray hole and the process chamber 110. Although rod 222c is labeled separately, the rod 222c may be a part of or included in shaft 222.

The magnetic fluid seal 222b may include a magnetic seal structure using a magnetic force, that is, a magnet, and may be implemented in various modifications.

The rotation motor 222a for opening and closing the spray hole may be positioned outside the process chamber 110, and may be sealed at a coupling with the process chamber 110 by the magnetic fluid seal 222b, and may thereby maintain a vacuum state in the process chamber 110.

A pipe 212 for gas supply protruding toward the upper portion of the process chamber 110 at the center of the showerhead body 210 may be positioned to protrude on the upper portion of the showerhead body 210, the rotation motor 222a for opening and closing the spray hole may be mounted on the upper portion of the pipe 212 for gas supply, so that the rod 222c is positioned to penetrate through the center of the pipe 212 for gas supply, and the gas supply pipe 210b of the reactant gas supply is connected to a side surface of the protruding pipe 212 for gas supply.

The rotating plate 221 for opening and closing the flow path may be in close contact with the bottom surface of the gas inlet space 210a and may be rotatably positioned thereon. The rotating plate 221 may be connected to the rod 222c of the rotation motor 222a for opening and closing the spray hole at the center thereof, and may be rotated by an operation of the rotation motor 222a for opening and closing the spray hole, and may thereby selectively open and close the first gas spray hole 211a or the second gas spray hole 211b, and may alternately open and close the plurality of first gas spray holes 211a and the plurality of second gas spray holes 211b.

The protruding pipe portion 212 for gas supply may be positioned at the center of the showerhead body 210 on the upper surface of the showerhead body 210 such as to uniformly supply a gas into the gas inlet space 210a.

In addition, since the rotation motor 222a for opening and closing the spray hole may be connected to the center of the rotating plate 221 for opening and closing the flow path to rotate the rotating plate 221 for opening and closing the flow path inside the showerhead body 210, the rotation motor 222a for opening and closing the spray hole may be mounted on the upper surface of the pipe 212 for gas supply positioned at the center of the showerhead body 210 so that the rod 222c penetrates through the center of the pipe 212 for gas supply.

Within the pipe 212 for gas supply, a flow path through which the reactant gas flows may be positioned around an outer circumference of the rod 222c, and the gas supply pipe 210b of the reactant gas supply may be connected to the side surface of the pipe 212 for gas supply, so that the reactant gas may be supplied from the center of the showerhead body 210, that is, the center of the fluid inlet space, through the pipe 212 for gas supply.

The rotating plate 221 for opening and closing the flow path may be coupled to the showerhead body 210, so that a position of the rotating plate 221 for opening and closing the flow path is fixed, and a rotation guide rail 223 that seals the rotating plate 221 for opening and closing the flow path and the bottom surface of the gas inlet space 210a is positioned to protrude on an outer circumferential surface.

As an example, the rotation guide rail 223 may include a first ring rail 223a positioned to protrude on an outer circumferential surface of the rotating plate 221 for opening and closing the flow path and inserted into the inner side surface of the showerhead body 210, a second ring rail 223b positioned to protrude above or below the first ring rail 223a and inserted into the inner side surface of the showerhead body 210, and a third ring rail 223c positioned to protrude inward or outward from an end of the second ring rail 223b and inserted into the inner side surface of the showerhead body 210.

In addition, a bearing may be provided between the rotation guide rail 223 and the showerhead body 210 to enable the rotating plate 221 for opening and closing the flow path to smoothly rotate.

The rotation guide rail 223 may allow the rotating plate 221 for opening and closing the flow path to rotate in close contact with the bottom surface of the gas inlet space 210a through the first ring rail 223a positioned horizontally, the second ring rail 223b positioned vertically from the end of the first ring rail 223a, and the third ring rail 223c positioned horizontally from the second ring rail 223b, and may prevent the reactant gas from leaking between the rotating plate 221 for opening and closing the flow path and the showerhead body 210 by sealing the space between the rotating plate 221 for opening and closing the flow path and the showerhead body 210.

As an example, the rotation motor 222a for opening and closing the spray hole may be a step motor. Since the step motor may be rotated at a certain angle by a pulse signal, the step motor may accurately rotate the rotating plate 221 for opening and closing the flow path at a preset angle, that is, an angle between the first straight line portion L1 and the second straight line portion L2 so that the first gas spray hole 211a and the second gas spray hole 211b may be alternately opened.

The rotation motor 222a for opening and closing the spray hole may be a step motor, and may rotate the rotating plate 221 for opening and closing the flow path at a preset angle at time intervals to allow the reactant gas to be sprayed alternately from the first gas spray hole 211a or the second gas spray hole 211b for a certain period of time.

The showerhead 200 according to an embodiment of the present disclosure may alternately spray the reactant gas through the plurality of first gas spray holes 211a and the plurality of second gas spray holes 211b by rotating the rotating plate 221 for opening and closing the flow path to alternately open the plurality of first gas spray holes 211a and the plurality of second gas spray holes 211b inclined in opposite directions.

The showerhead 200 according to an embodiment of the present disclosure may evenly spray the reactant gas over the entire surface of the substrate by alternately opening the plurality of first gas spray holes 211a and the plurality of second gas spray holes 211b inclined in opposite directions, and may enable a design that further reduces the process gap through an occurrence of dislocation.

In addition, the showerhead according to an embodiment of the present disclosure may further include a second shaft 230 that rotates the showerhead body 210.

The pipe 212 for gas supply may include a fixed pipe 212a fixed to the process chamber 110, and a rotating pipe 212b rotatably coupled to the fixed pipe 212a about an axial direction, and the second shaft 230 may include a showerhead rotation motor 231 (e.g., a second motor) and a transmission 232 that receives a rotational force of the showerhead rotation motor 231 to rotate the rotating pipe 212b.

As an example, the transmission 232 may include a first gear 232a mounted on the rod 231b of the showerhead rotation motor 231, and a second gear 232b mounted on an outer circumferential surface of the rotating pipe 212b and rotated by being engaged with the first gear 232a. Rod 231b may be included with, or the same as, the second shaft 230.

As the second gear 232b engages and rotates with the first gear 232a mounted on the rod 231b of the showerhead rotation motor 231, the transmission 232 may rotate the rotating pipe 212b using the rotational force of the showerhead rotation motor 231 to rotate the showerhead body 210.

It should be noted that the transmission 232 may be implemented in various modifications by using a variety of rotational force transmission structures such as a belt structure in addition to the gear structure.

The showerhead rotation motor 231 may be mounted on the upper portion of the process chamber 110, so that the rod 231b is positioned to penetrate through the upper surface of the process chamber 110, and a magnetic fluid seal 231a is positioned between the rod 231b and the process chamber 110 to seal the inside of the process chamber 110.

The magnetic fluid seal may include a magnetic seal structure using a magnetic force, that is, a magnet, and may be implemented in various modifications.

The second shaft 230 may uniformly and evenly supply the reactant gas over the entire surface of the substrate by rotating the showerhead body 210 having the plurality of inclined spray holes.

The showerhead 200 according to an embodiment of the present disclosure may alternately spray the reactant gas through the plurality of first gas spray holes 211a and the plurality of second gas spray holes 211b by rotating the rotating plate 221 for opening and closing the flow path to alternately open the plurality of first gas spray holes 211a and the plurality of second gas spray holes 211b inclined in opposite directions, and may enable a design that uniformly and evenly sprays the reactant gas over the entire surface of the substrate by rotating the showerhead body 210 using the second shaft 230 and reduces the process gap through an occurrence of dislocation.

The substrate treatment apparatus 100 including the showerhead 200 according to an embodiment of the present disclosure illustrated in FIG. 1, the reactant gas may be evenly and uniformly supplied to the substrate positioned in each pocket by rotating the showerhead body 210, when the disk is rotated by the first rotating and the substrate positioned in each pocket of the disk is rotated by the second rotating portion.

Furthermore, when the disk is rotated by the first rotating assembly and the substrate positioned in each pocket of the disk is rotated by the second rotating assembly, the showerhead according to an embodiment of the present disclosure may alternately spray the reactant gas through the plurality of first gas spray holes 211a and the plurality of second gas spray holes 211b by rotating the rotating plate 221 for opening and closing the flow path to alternately open the plurality of first gas spray holes 211a and the plurality of second gas spray holes 211b inclined in opposite directions, and may enable a design that uniformly and evenly sprays the reactant gas over the entire surface of the substrate by rotating the showerhead body 210 using the second shaft 230 and reduces the process gap through an occurrence of dislocation.

Accordingly, by supplying the reactant gas uniformly and evenly to each of the plurality of substrates positioned in each pocket, the thickness of the thin film of each substrate may be uniformly formed. Defects may be prevented from occurring when simultaneously treating the plurality of substrates, and productivity may be significantly increased.

According to an embodiment of the present disclosure, since the gap between the substrate and the spray surface of the showerhead, that is, the process gap, may be reduced by forming the gas spray hole for spraying the reactant gas on the substrate to be inclined, productivity of a process of depositing a thin film may be improved.

In addition, according to an embodiment of the present disclosure, the amount of used gas may be reduced by reducing the gap between the substrate and the spray surface of the showerhead, that is, the process gap, the removal time of unnecessary reactant gas and by-product in the space may be shortened, and running costs may be reduced by reducing the amount of used reactant gas.

According to the present disclosure, the reactant gas may be evenly sprayed over the entire surface of the substrate by alternately changing the spray direction of the reactant gas to the left and right, dislocation may occur and, the process gap may be further reduced.

It should be noted that the present disclosure is not limited to the above-described embodiments, and may be implemented with various changes without departing from the gist of the present disclosure, and these are included in the configuration of the present disclosure.

1. A showerhead provided on a process chamber, the showerhead comprising:
a body;
an inlet space in which a fluid is configured to flow through; and
a plurality of spray holes provided on a lower surface of the body and configured to spray the fluid toward a substrate,
wherein the plurality of spray holes are inclined at an angle with respect to the lower surface of the body.

2. The showerhead of claim 1, wherein a separation of the plurality of spray holes increases from a center of the lower surface of the body to an edge of the lower surface of the body.

3. The showerhead of claim 1, wherein the inclination angle of the plurality of spray holes with respect to the lower surface of the body is from 30° to 60°.

4. (canceled)

5. (canceled)

6. (canceled)

7. The showerhead of claim 1, wherein the plurality of spray holes comprises:
a plurality of first spray holes with an inclination angle in a first direction, and a plurality of second spray holes with an inclination angle in a second direction different from the first direction, and
wherein the body comprises a valve configured to selectively open and close a flow of fluid through the plurality of first spray holes and the plurality of second spray holes.

8. The showerhead of claim 7, wherein the valve comprises:
a plate comprising a plurality of openings corresponding with the plurality of first spray holes and the plurality of second spray holes, the plate configured to rotate and selectively align the plurality of openings with the plurality of first spray holes or the plurality of second spray holes within the inlet space; and
a shaft configured to rotate the plate between an opened state and a closed state.

9. The showerhead of claim 8, wherein the plurality of first spray holes are provided in one or more first straight lines passing through a center of the lower surface of the body,
wherein the plurality of second spray holes are provided in one or more second straight lines passing through the center of the lower surface of the body, and
wherein the one or more first straight lines alternate with the one or more second straight lines about the center of the lower surface of the body.

10. The showerhead of claim 9, wherein the plurality of openings on the plate are provided in a plurality of straight lines corresponding to the plurality of first spray holes and the plurality of second spray holes, and
wherein, in the opened state, the plurality of openings are aligned with either the plurality of first spray holes or the plurality of second spray holes.

11. The showerhead of claim 8, wherein the valve further comprises:
a first motor configured to rotate the plate between the opened state and the closed state; and
a magnetic fluid seal providing a seal between the shaft and the process chamber.

12. The showerhead of claim 10, wherein the valve further comprises a first motor connected to the shaft and configured to rotate the plate between the opened state and the closed state, and
wherein the first motor is a step motor configured to rotate the plate at a preset angle in predetermined time intervals and alternately align the plurality of openings with the plurality of first spray holes and the plurality of second spray holes at each predetermined time interval.

13. The showerhead of claim 1, further comprising a second shaft configured to rotate the body of the showerhead.

14. The showerhead of claim 13, further comprising a pipe protruding from the body and connected to a fluid supply and configured to supply the fluid into the inlet space,
wherein the pipe comprises:
a fixed pipe fixed to the process chamber; and
a rotating pipe rotatably coupled to the fixed pipe about an axial direction, and
wherein the second shaft comprises:
a second motor; and
a transmission connected to the second motor and configured to transmit a rotational force to the rotating pipe.

15. The showerhead of claim 14, wherein the second motor is provided on an upper portion of the process chamber,
wherein the second shaft is provided through a surface of the process chamber, and
wherein a magnetic fluid seal is provided between the second shaft and the process chamber.

16. A substrate treatment apparatus comprising:
a process chamber comprising a substrate treatment space and a disk on which a substrate is seated; and
the showerhead of claim 1 provided on an upper side of the disk in the process chamber and configured to spray a fluid toward the substrate seated on the disk.

17. The substrate treatment apparatus of claim 16, wherein the disk is provided with a plurality of pockets onto which the substrate is seated, and
the plurality of pockets are configured to rotate on a plane by a first rotating assembly.

18. The substrate treatment apparatus of claim 17, wherein the disk is provided on an bottom surface of the process chamber and configured to rotate by a second rotating assembly.

19. The substrate treatment apparatus of claim 16, wherein a separation of the plurality of spray holes of the showerhead increases from a center of the lower surface of the body to an edge of the lower surface of the body.

20. The substrate treatment apparatus of claim 16, wherein the inclination angle of the plurality of spray holes with respect to the lower surface of the body is from 30° to 60°.

21. A showerhead provided on a process chamber, the showerhead comprising:
a body;
a pipe protruding from the body and connected to a fluid supply;
an inlet space configured to accommodate a fluid from the fluid supply;
a plurality of spray holes provided on a lower surface of the body and configured to spray the fluid toward a substrate; and
a valve configured to selectively open and close a flow of fluid through the plurality of spray holes,
wherein the plurality of spray holes are inclined at an angle with respect to the lower surface of the body.

22. The showerhead according to claim 21, further comprising a second shaft configured to rotate the body of the showerhead,
wherein the valve comprises:
a plate comprising a plurality of openings corresponding with the plurality of spray holes, the plate configured to rotate and selectively align the plurality of openings with a number of the plurality of spray holes;
a shaft configured to rotate the plate between an opened state and a closed state.

23. The showerhead according to claim 21, wherein an inclination angle of a number of spray holes at an edge of the lower surface of the body is larger than an inclination angle of a number of spray holes in a center of the lower surface of the body.
